(19) United States
(12) Patent Application Publication
(10) Pub. No.: US 2026/0005083 A1
(43) Pub. Date: Jan. 1, 2026

(54) TOOLING HOLE FOR HYBRID PANEL ASSEMBLY

(71) Applicant: Intel Corporation, Santa Clara, CA (US)

(72) Inventors: Brandon C. MARIN, Gilbert, AZ (US); Jeremy D. ECTON, Gilbert, AZ (US); Gang DUAN, Chandler, AZ (US); Srinivas Venkata Ramanuja PIETAMBARAM, Chandler, AZ (US)

(21) Appl. No.: 18/758,076

(22) Filed: Jun. 28, 2024

(51) Int. Cl. H01L 23/15; H01L 23/538; H01L 23/58

(52) U.S. Cl. CPC H01L 23/15; H01L 23/5384; H01L 23/585; H10D 1/20

(57) ABSTRACT

Embodiments disclosed herein include an apparatus that comprises a substrate, where the substrate comprises a glass layer. In an embodiment, a first cavity is formed through a thickness of the substrate from a first surface of the substrate to a second surface of the substrate, and a second cavity is formed through the thickness of the substrate. In an embodiment, a layer is over the substrate, where the layer at least partially fills the first cavity and the second cavity. In an embodiment, a plug is within the first cavity, where a first portion of the layer separates the plug from the substrate. In an embodiment, a component is in the second cavity, where a second portion of the layer separates the component from the substrate.

### BACKGROUND

Electronics packaging substrates often include a core. Existing core materials include organic dielectrics that may include fiber reinforcement materials. As devices continue to become more complex, better performing core materials are desired. A package core that includes a solid glass layer is one potential option. Glass cores enable stiffer substrates, flatter surfaces, and can improve electrical performance.

However, the fragile nature of glass makes full-size glass panel edges extremely vulnerable to damage due to frequent contact of the edges during handling and processing. Accordingly, the glass substrates are often assembled into a hybrid panel that includes an organic panel that surrounds the glass substrate. A dielectric layer, such as a buildup film, is applied over the glass substrate to secure the glass substrate to the frame. In some instances, cavities are formed through the glass substrate to allow for the formation of integrated passive devices, such as inductors. In practice, the cavities are formed in each hybrid panel sequentially, since the stacked hybrid panels cannot be aligned properly with optical alignment. As such, high volume manufacturing (HVM) is limited, and the cost of assembling glass core packages with a hybrid panel process is high.

### BRIEF DESCRIPTION OF THE DRAWINGS

FIG. 1A is a cross-sectional illustration of a portion of a package substrate with a glass core that includes a first cavity that is plugged and a second cavity with an integrated passive device, in accordance with an embodiment.

FIG. 1B is a plan view illustration of a portion of a package substrate with a glass core that includes a first cavity that is plugged and a second cavity with an integrated passive device, in accordance with an embodiment.

FIG. 1C is a cross-sectional illustration of a portion of a package substrate with a glass core that includes a first cavity that is plugged and a second cavity with an integrated passive device, in accordance with an embodiment.

FIG. 1D is a plan view illustration of a portion of a package substrate with a glass core that includes a first cavity that is plugged and a second cavity with an integrated passive device, in accordance with an embodiment.

FIG. 2 is a cross-sectional illustration of a plurality of hybrid panels that are physically aligned with pins in order to accurately form a plurality of cavities through the hybrid panels, in accordance with an embodiment.

FIGS. 3A-3K are cross-sectional illustrations depicting a process for forming a package substrate with plugged holes and an integrated passive device, in accordance with an embodiment.

FIG. 4 is a flow diagram of a process for forming a package substrate with a glass core that includes a plug and an integrated passive device, in accordance with an embodiment.

FIGS. 5A-5I are cross-sectional illustrations depicting a process for forming a package substrate from a hybrid panel with holes for pin alignment in order to accurately place an integrated passive device within a glass core of the package substrate, in accordance with an embodiment.

FIG. 6 is a cross-sectional illustration of an electronic system with a package substrate that comprises a glass core with a plugged hole and an integrated passive device, in accordance with an embodiment.

FIG. 7 is a schematic of a computing device built in accordance with an embodiment.

### EMBODIMENTS OF THE PRESENT DISCLOSURE

Described herein are hybrid panels with glass substrates that include a tooling hole for improved alignment, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, glass core technology may be an ideal replacement for organic core solutions in advanced packaging applications. However, high volume manufacturing (HVM) processes are currently limited in the fabrication of such package substrates. One significant limitation is that it is not currently possible to align multiple hybrid panels that are arranged in a stack with existing optical approaches. This is particularly problematic when holes need to be formed through the glass substrates. For example, holes may be needed for the integration of passive devices (e.g., inductors, capacitors, etc.) into the glass core. Without the ability to align multiple hybrid panels in a stack, each hybrid panel needs to have holes drilled separately, which can result in a significant decrease in throughput.

Accordingly, embodiments disclosed herein may further comprise the fabrication of one or more tooling holes through the glass substrate of the hybrid panel. In an embodiment, the tooling holes may be used to receive an alignment pin. A plurality of such hybrid panels may be stacked over each other with the alignment pin passing through the tooling holes in each of the hybrid panels. This allows for proper mechanical alignment of the plurality of hybrid panels. Once aligned, holes for the passive devices may be formed through each of the hybrid panels in the stack with a single drilling process. Accordingly, multiple hybrid panels can be processed in parallel in order to increase throughput. As such, the overall cost to fabricate the glass core package substrate is reduced.

In some embodiments, the tooling holes are provided through the glass substrate of the hybrid panel outside of an active area. In such an embodiment, the tooling holes may be removed from the package substrate during a singulation process. However, in other embodiments the tooling holes may be provided within an active area of the package substrate. In such instances, the tooling holes may persist into the final structure of the package substrate.

In an embodiment, the tooling holes may be filled with an electrically insulating plug, such as an organic dielectric material. The plug may be used to prevent the presence of a void within the package substrate. In some embodiments, the plug may be lined by a metallic liner as well. For example, a metallic annulus may be provided along an entire height of the plug. As such, even when the plug is the same material as the surrounding buildup layers, the plug may still be discernable from the surrounding layers. Though, in some embodiments the metallic liner may be omitted.

In an embodiment, the passive device that is integrated into the glass core may be an integrated passive device. That is, the passive device may be fabricated directly into the glass core as opposed to being a discrete device that is placed within the glass core. For example, an integrated passive device may comprise a coaxial magnetic composite core inductor. Such an inductor may comprise a magnetic shell with a conductive liner on an interior surface of the magnetic shell. An electrically insulating plug may be provided within the conductive liner.

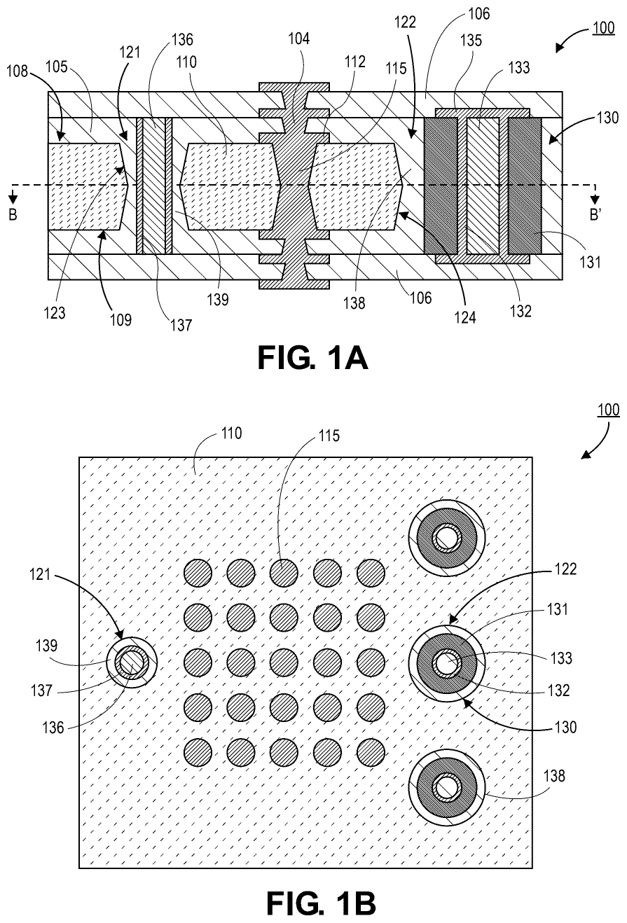

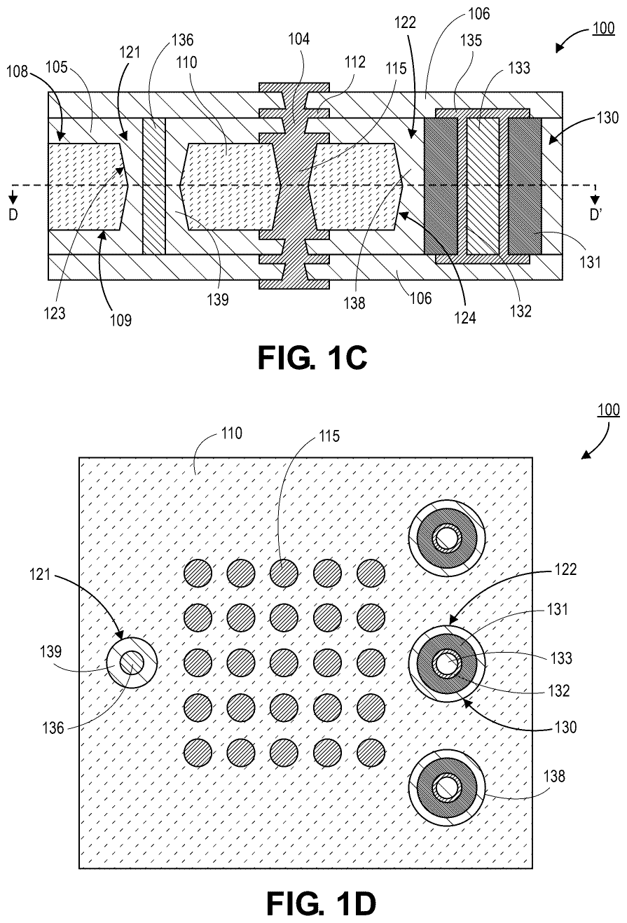

Referring now to FIG. 1A, a cross-sectional illustration of a portion of a package substrate 100 is shown, in accordance with an embodiment. In an embodiment, the package substrate 100 may comprise a glass core 110 with one or more vias 115 through a thickness of the glass core 110 between a first surface 108 (top surface) and a second surface 109 (bottom surface). In the illustrated embodiment, the via 115 comprises an hourglass shaped cross-section. Though, embodiments may also comprise a via 115 with a single taper or a via 115 with substantially vertical sidewalls. In an embodiment, a first cavity 121 and a second cavity 122 may also be provided through a thickness of the glass core 110. In an embodiment, the first cavity 121 and the second cavity 122 may have sidewalls 123 and 124, respectively, that have tapered sidewalls.

In an embodiment, the glass core 110 may be substantially all glass. The glass core 110 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 110 may be distinguished from, for example, the “prepreg” or “FR4” core of a Printed Circuit Board (PCB) substrate which typically comprises glass fibers embedded in a resinous organic material, such as an epoxy.

The glass core 110 may have any suitable dimensions. In a particular embodiment, the glass core 110 may have a thickness that is approximately 50 μm or greater. For example, the thickness of the glass core 110 may be between approximately 50 μm and approximately 1.4 mm. Though, smaller or larger thicknesses may also be used. The glass core 110 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 110 (from an overhead plan view) may be between approximately 10 mm×10 mm and approximately 250 mm×250 mm. In an embodiment, the glass core 110 may have a first side that is perpendicular or orthogonal to a second side. In a more general embodiment, the glass core 110 may comprise a rectangular prism volume with sections (e.g., vias) removed and filled with other materials (e.g., metal, etc.).

The glass core 110 may comprise a single monolithic layer of glass. In other embodiments, the glass core 110 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 110 may each have a thickness less than approximately 50 μm. For example, discrete layers of glass in the glass core 110 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 110 may be any suitable glass formulation that has the necessary mechanical robustness and compatibility with semiconductor packaging manufacturing and assembly processes. For example, the glass core 110 may comprise aluminosilicate glass, borosilicate glass, alumino-borosilicate glass, silica, fused silica, or the like. In some embodiments, the glass core 110 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 110 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 110 may comprise at least 23 percent silicon (by weight) and at least 26 percent oxygen (by weight). In some embodiments, the glass core 110 may further comprise at least 5 percent aluminum (by weight).

In an embodiment, a buildup layer 105 may be provided over and under the glass core 110. In an embodiment, the buildup layer 105 may also at least partially fill the first cavity 121 and the second cavity 122. The buildup layer 105 may be directly on the glass core 110 in some embodiments. In other embodiments, a buffer layer (not shown) may be provided between the buildup layer 105 and the glass core 110. A pad 112 may be provided on the glass core 110 over the via 115. Vias 104 and additional overlying pads 112 may also be provided over the first pad 112. An additional buildup layer 106 may be provided over the first buildup layer 105. It is to be appreciated that any number of buildup layers 106 (with integrated electrical routing (e.g., pads, traces, vias, etc.) may be provided in the package substrate 100.

In an embodiment, a plug 136 may be provided through the first cavity 122. In an embodiment, the plug 136 may comprise an organic dielectric material. In some instances, the plug 136 may include the same material as the buildup layer 105. The plug 136 may extend past the first surface 108 and the second surface 109 of the glass core 110. In an embodiment, sidewalls of the plug 136 may be substantially vertical. That is, the sidewalls of the plug 136 may be oriented substantially orthogonally to the first surface 108 of the glass core 110.

In some embodiments, a metallic liner 137, such as a copper liner, may be provided along the sidewalls of the plug 136. The metallic liner 137 may be considered a metallic annulus in some embodiments. The metallic liner 137 may extend along an entire height of the plug 136. In an embodiment, the metallic liner 137 may be electrically floating. That is, the metallic liner 137 may not be electrically coupled to any other electrical features within the package substrate 100. The metallic liner 137 and the plug 136 may be separated from the sidewall 123 of the first cavity 121 by a portion 139 by the buildup layer 105.

In an embodiment, a passive device 130 may be provided within the second cavity 122. The passive device 130 may be an integrated passive device, such a coaxial magnetic composite core inductor. For example, the passive device 130 may comprise a magnetic shell 131. An interior surface of the magnetic shell 131 may be lined by an electrically conductive liner 132, and the electrically conductive liner 132 may be filled by an electrically insulating plug 133. Pads 135 may be provided above and below the electrically conductive liner 132. In an embodiment, the passive device 130 may have substantially vertical sidewalls that are oriented substantially orthogonally to the first surface 108 of the glass core 110. Additionally, a portion 138 of the buildup layer 105 may be provided between the sidewall 124 of the second cavity 122 and the sidewall of the passive device 130.

Referring now to FIG. 1B, a plan view illustration of the package substrate 100 through the line B-B′ in FIG. 1A is shown, in accordance with an embodiment. As shown, a plurality of vias 115 may be distributed across the core 110. The first cavity 121 may be outside of the main group of vias 115. As shown, the plug 136 may be circular and surrounded by the metallic liner 137 and a portion 139 of the buildup layer 105. One or more second cavities 122 may also be provided outside of the main group of vias 115. Devices 130 may be provided in the one or more second cavities 122. For example, the devices 130 may comprise a magnetic shell 131, an electrically conductive liner 132, and an insulating plug 133. The devices 130 may be spaced apart from sidewalls of the second cavities 122 by a portion 138 of the buildup layer 105. As shown, the first cavity 121 may have a diameter that is smaller than a diameter of the second cavity 122.

Referring now to FIG. 1C, a cross-sectional illustration of a portion of a package substrate 100 is shown, in accordance with an additional embodiment. In an embodiment, the package substrate 100 in FIG. 1C may be similar to the package substrate 100 in FIG. 1A, with the exception of the plug 136. Instead of the plug 136 being lined with a metallic liner, the plug 136 may be in direct contact with the buildup layer 105. In some embodiments, the plug 136 and the buildup layer 105 may comprise different materials, so that the plug 136 is easily identifiable. Though, in other embodiments, the plug 136 may be the same material as the buildup layer 105. In some instances, a seam may be present between the plug 136 and the buildup layer 105. Though, other embodiments may include a first cavity 121 that appears to be entirely filled by a single layer. In such an embodiment, a first cavity 121 without any identifying internal features may be present as an indication that embodiments described herein were used.

Referring now to FIG. 1D, a plan view illustration of the package substrate 100 through the line D-D′ in FIG. 1C is shown, in accordance with an embodiment. The package substrate 100 in FIG. 1D may be similar to the package substrate 100 in FIG. 1B, with the exception of the first cavity 121. As shown, the plug 136 is surrounded by the portion 139 of the buildup layer 105.

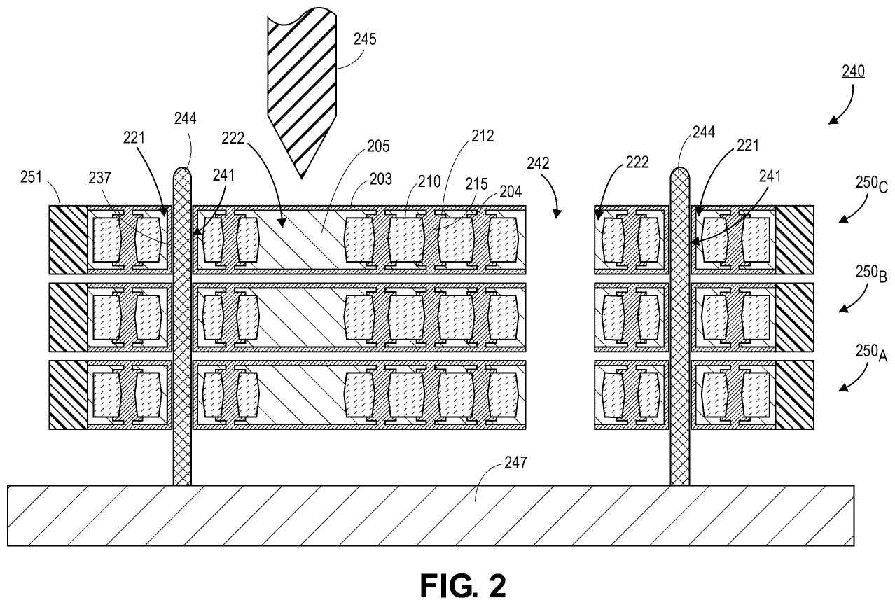

Referring now to FIG. 2, a cross-sectional illustration of an assembly station 240 for a plurality of hybrid panels 250A-250c is shown, in accordance with an embodiment. Each of the hybrid panels 250A-250c may comprise a glass substrate 210. The glass substrate 210 may be similar to any of the glass formulations described in greater detail herein. In an embodiment, vias 215 may pass through a thickness of the glass substrate 210. Vias 204 through a buildup layer 205 may couple pads 212 over the vias 215 in the glass substrate 210 to a metal layer 203 over and under the buildup layer 205. In an embodiment, first cavities 221 and second cavities 222 may be provided through the glass substrate 210.

As shown, the plurality of hybrid panels 250A-250c may be arranged in a vertical stack over a backing board 247. In an embodiment, the hybrid panels 250A-250c may be mechanically aligned with each other by one or more pins 244 that extend up from the backing board 247. In an embodiment, the pins 244 may pass through tooling holes 241 that pass through the hybrid panels 250A-250c. The tooling holes 241 may be formed with any suitable process, as will be described in greater detail herein. For example, the tooling holes 241 may be formed with a drilling process that passes through a first cavity 221 in each of the hybrid panels 250A-250c. In an embodiment, the tooling holes 241 may be lined with a metal liner 237, and the metal liner 237 may be separated from a sidewall of the first cavity 221 by a portion of the buildup layer 205.

In an embodiment, the buildup layer 205 may secure the glass substrate 210 to an external frame 251 that surrounds a perimeter of the glass substrate 210. The external frame 251 may comprise an organic dielectric material. The frame 251 may provide protection to the fragile glass substrate 210 and allow for processing the hybrid panels 250A-250c with processing tools designed to handle traditional organic panels.

In an embodiment, the plurality of hybrid panels 250A-250c are arranged in a vertical stack in order to allow for substantially parallel processing for the plurality of hybrid panels 250A-250c. For example, a hole formation process may be used in order to form one or more holes 242 through a thickness of the hybrid panels 250A-250c with a single pass of a drill bit 245. For example, the holes 242 on the right side of FIG. 2 have been drilled, and holes 242 are about to be drilled on the left side of FIG. 2 with the drill bit 245. In an embodiment, the holes 242 are formed through second cavities 222 in the glass substrates 210. The holes 242 may be spaced apart from edges of the second cavities 222 by a portion of the buildup layer 205.

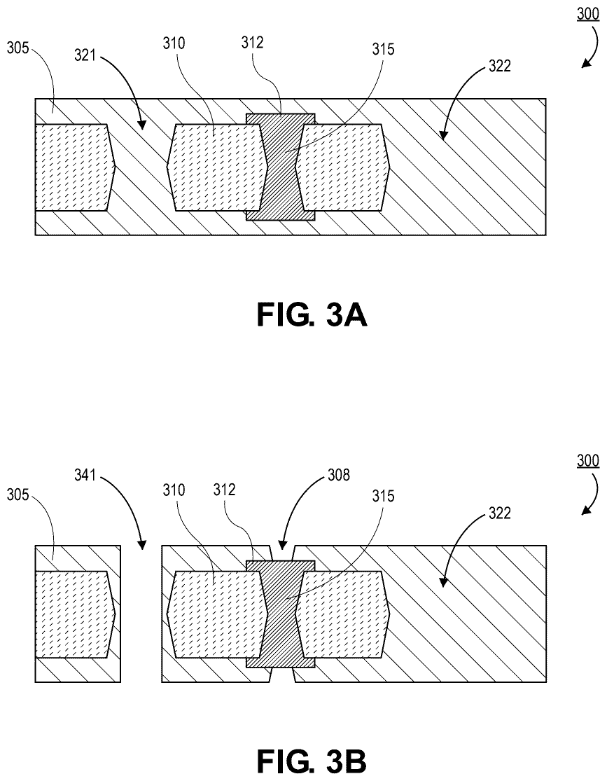

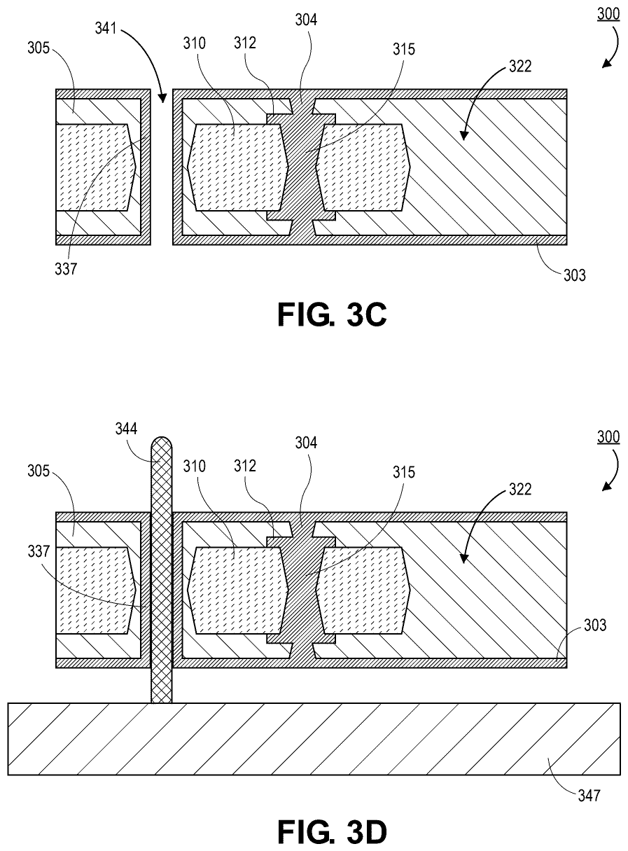

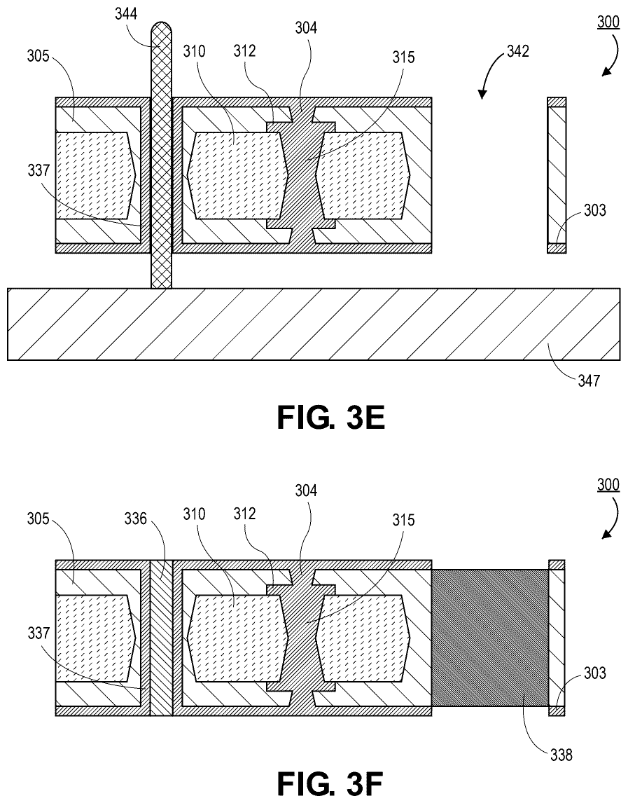

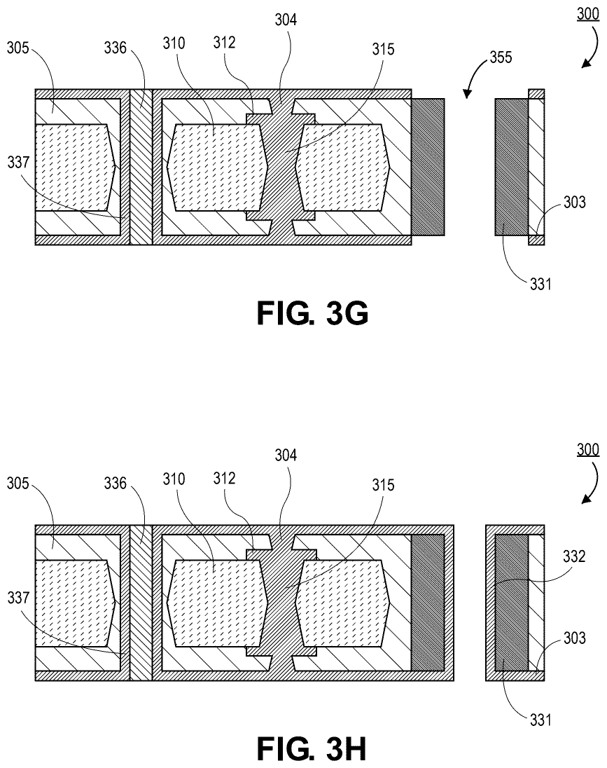

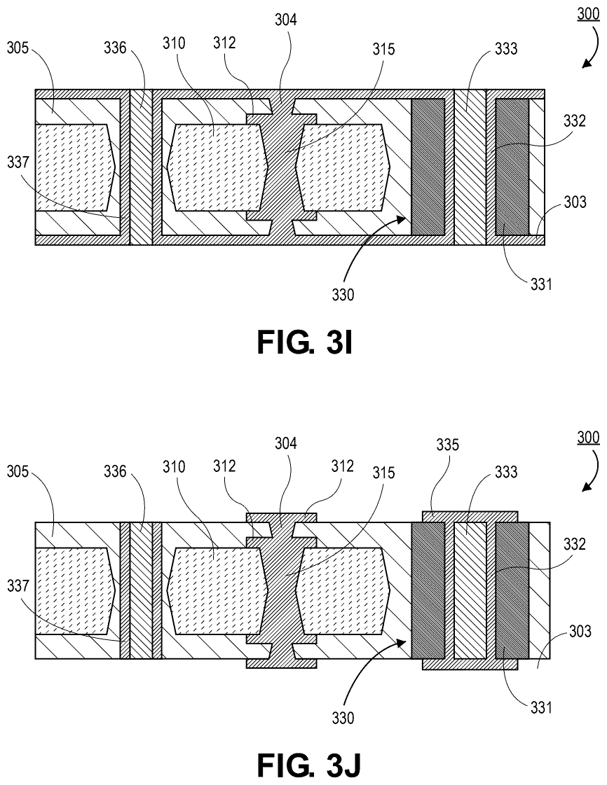

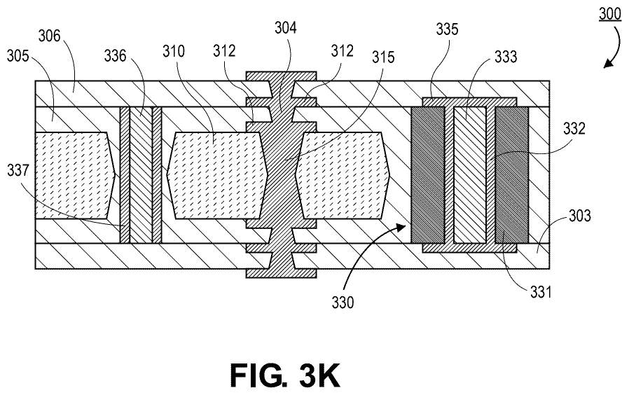

Referring now to FIGS. 3A-3K, a series of cross-sectional illustrations depicting a process for forming a portion of a package substrate 300 is shown, in accordance with an embodiment. The illustrated portions of the package substrate 300 highlight a single unit. Though, it is to be appreciated that the package substrate 300 may be part of a larger hybrid panel (not shown) during some of the processing operations shown in FIGS. 3A-3K.

Referring now to FIG. 3A, a cross-sectional illustration of a portion of a package substrate 300 is shown, in accordance with an embodiment. In an embodiment, the package substrate 300 may comprise a glass core 310. The glass core 310 may be similar to any of the glass cores and/or glass layers described in greater detail herein. In an embodiment, a via 315 may be provided through a thickness of the glass core 310. The via 315 may be formed with any suitable process. For example, a laser assisted etching process may be used to form openings for the via 315. In the illustrated embodiment, the via 315 has an hourglass shaped cross-section. Though, in other embodiments the via 315 may have a single taper or substantially vertical sidewalls. Pads 312 may be provided over and under the via 315.

In an embodiment, the glass core 310 may also comprise a first cavity 321 and a second cavity 322 through a thickness of the glass core 310. The first cavity 321 and the second cavity 322 may have sidewalls with a double taper or any other suitable profile. The glass core 310 may be embedded in a dielectric layer 305. The dielectric layer 305 may comprise a buildup film or any other suitable organic dielectric material. The dielectric layer 305 may also fill the first cavity 321 and the second cavity 322.

Referring now to FIG. 3B, a cross-sectional illustration of the portion of the package substrate 300 after a tooling hole 341 is formed through the dielectric layer 305 within the first cavity 321 is shown, in accordance with an embodiment. In an embodiment, the tooling hole 341 may be formed with a drilling process or the like. As shown, a diameter of the tooling hole 341 is smaller than a minimum diameter of the first cavity 321 so that portions of the dielectric layer 305 remain between the tooling hole 341 and the sidewalls of the first cavity 321. Via openings 308 may also be formed through a portion of the dielectric layer 305 in order to expose portions of the pad 312.

Referring now to FIG. 3C, a cross-sectional illustration of the portion of the package substrate 300 after a plating process is shown, in accordance with an embodiment. In an embodiment, the plating process may be used to form a metal layer 303 (e.g., a copper layer) over the top and bottom surfaces of the dielectric layer 305. The plating process may also result in the formation of a metallic liner 337 along the sidewalls of the tooling hole 341. The plating process may also be used to form vias 304 over the pads 312. In an embodiment, the plating process may be an electroplating process. For example, a seed layer (not shown) may be deposited over surfaces of the dielectric layer 305 first in order to allow for the plating.

Referring now to FIG. 3D, a cross-sectional illustration of the portion of the package substrate 300 after a pin 344 from a backing board 347 is inserted through the tooling hole 341 of the package substrate 300 is shown, in accordance with an embodiment. While a single package substrate 300 is placed over the backing board 347, it is to be appreciated that a plurality of devices may be vertically stacked (similar to FIG. 2) in order to process the plurality of devices substantially in parallel. As described above, the pin 344 enables mechanical alignment of the package substrate 300 in order to allow for accurate formation of a subsequent hole through the plurality of devices in parallel.

Referring now to FIG. 3E, a cross-sectional illustration of the portion of the package substrate 300 after a hole 342 is formed through the second cavity 322 of the package substrate 300 is shown, in accordance with an embodiment. In an embodiment, the hole 342 may be formed with a mechanical drilling process. As shown, a portion of the dielectric layer 305 may separate the sidewall of the hole 342 from a sidewall surface of the second cavity 322.

Referring now to FIG. 3F, a cross-sectional illustration of the portion of the package substrate 300 after the pin 344 is removed and a magnetic layer 338 is disposed in the hole 342 is shown, in accordance with an embodiment. In an embodiment, the magnetic layer 338 may comprise a curable magnetic paste or the like that is dispensed into the hole 342. In some embodiments, a plug 336 may also be dispensed into the tooling hole 341 after the pin 344 is removed. The plug 336 may be an organic dielectric material, such as a buildup film or the like. Though, in other embodiments, the plug 336 may also comprise a magnetic material similar to the magnetic layer 338. In such an embodiment, a single material dispensing process may be used to fill the tooling hole 341 and the hole 342.

Referring now to FIG. 3G, a cross-sectional illustration of the portion of the package substrate 300 after a hole 355 is formed through the magnetic layer 338 to form a magnetic shell 331 is shown, in accordance with an embodiment. In an embodiment, the hole 355 may be formed with a mechanical drilling process or the like.

Referring now to FIG. 3H, a cross-sectional illustration of the portion of the package substrate 300 after a metal layer 332 is plated onto the interior surfaces of the magnetic shell 331 is shown, in accordance with an embodiment. In an embodiment, the metal layer 332 may be plated with an electroplating process or the like.

Referring now to FIG. 3I, a cross-sectional illustration of the portion of the package substrate 300 after a plug 333 is dispensed into the hole 355 within the metal layer 332 is shown, in accordance with an embodiment. In an embodiment, the plug 333 may comprise an electrically insulating material.

Referring now to FIG. 3J, a cross-sectional illustration of the portion of the package substrate 300 after the metal layer 303 is patterned to define a pad 335 over the magnetic shell 331, the metal layer 332, and the plug 333 is shown, in accordance with an embodiment. In an embodiment, the resulting structure within the second cavity 322 may be considered an integrated passive device 330, such as an inductor. More particularly, the integrated passive device 330 may comprise a coaxial magnetic composite core inductor or the like.

Referring now to FIG. 3K, a cross-sectional illustration of the portion of the package substrate 300 after any number of additional buildup layers 306 are provided over the dielectric layer 305. The buildup layers 306 may comprise additional electrical routing, such as pads, vias, traces, and/or the like.

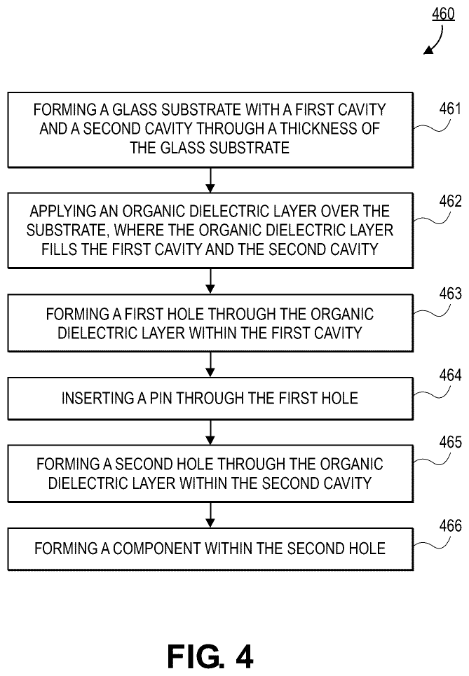

Referring now to FIG. 4, a flow diagram of a process 460 for forming a package substrate using a tooling hole is shown, in accordance with an embodiment. In an embodiment, the package substrate formed with the process 460 may be similar to any of the package substrates described in greater detail herein.

In an embodiment, the process 460 may begin with operation 461, which comprises forming a glass substrate with a first cavity and a second cavity through a thickness of the glass substrate. The process may continue with operation 462, which comprises applying an organic dielectric layer over the substrate. In an embodiment, the organic dielectric layer may fill the first cavity and the second cavity.

In an embodiment, the process 460 may continue with operation 463, which comprises forming a first hole through the organic dielectric layer within the first cavity. In an embodiment, the first hole may have sidewalls that are substantially vertical. In some instances, at least a portion of a sidewall of the first cavity may be oriented along a plane that intersects a plane of a sidewall of the first hole. The first hole may be formed with a mechanical drilling process or the like.

In an embodiment, the process 460 may continue with operation 464, which comprises inserting a pin through the first hole. In an embodiment, the pin may be used to align the glass substrate for subsequent processing. In some instances, a plurality of similar glass substrates are all aligned with a single pin that passes through a first hole in each of the glass substrates.

In an embodiment, the process 460 may continue with operation 465, which comprises forming a second hole through the organic dielectric layer within the second cavity. In an embodiment, the second hole is formed while the pin is inserted through the first hole. Accordingly, the alignment of the second hole can have high precision. The second hole may be formed with a mechanical drilling process or the like. In an embodiment, the second hole may have a diameter that is different than a diameter of the first hole. For example, the second hole may have a larger diameter than the first hole.

In an embodiment, the process 460 may continue with operation 466, which comprises forming a component within the second hole. In an embodiment, the component may be an integrated component, such as an integrated inductor or other passive device. For example, the component may comprise a coaxial magnetic composite core inductor or the like. Though, the component may also include a discrete component device that is placed into the second hole. The component may also be an active electrical device (e.g., comprising a transistor, diode, etc.) in some embodiments.

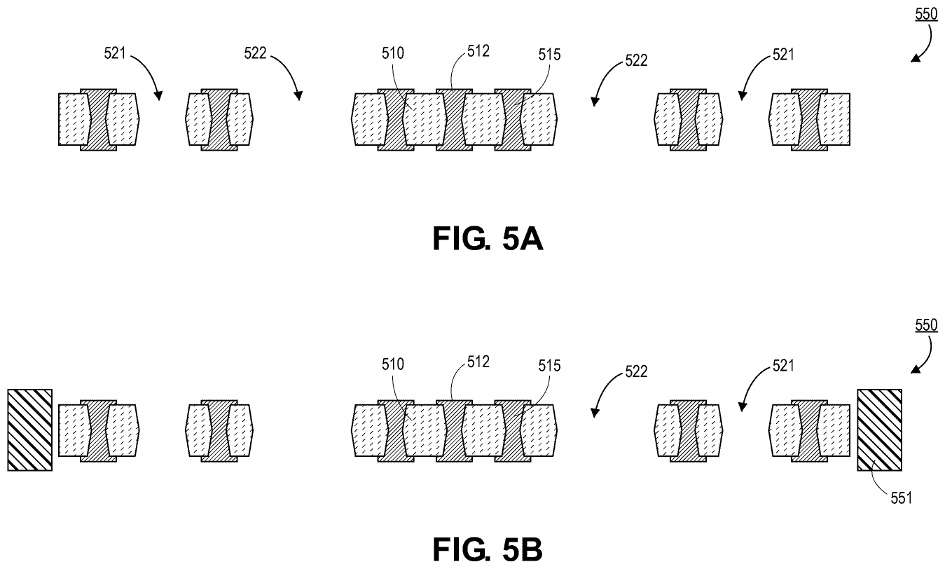

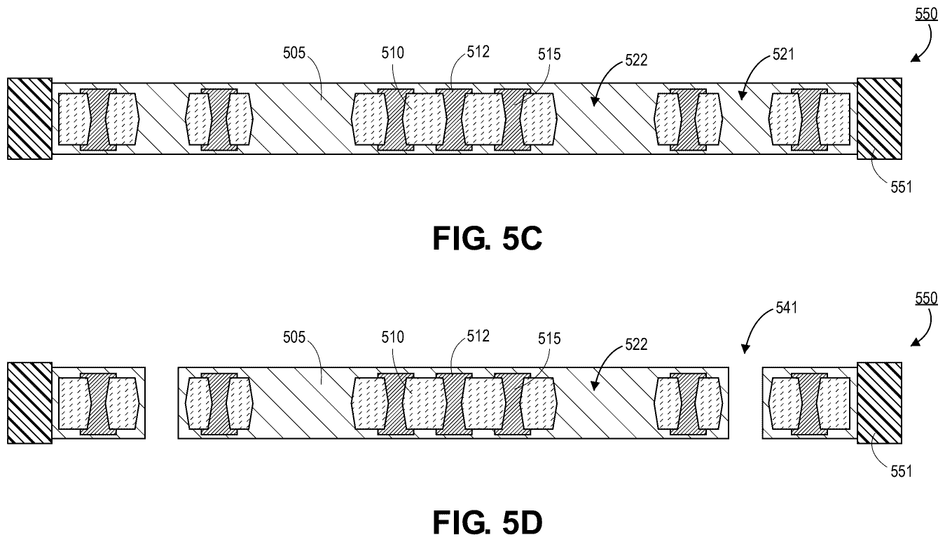

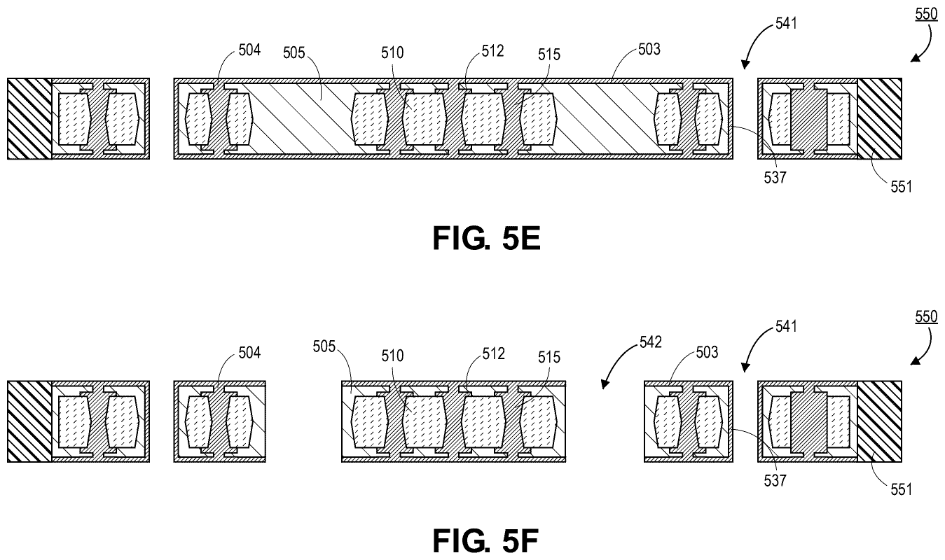

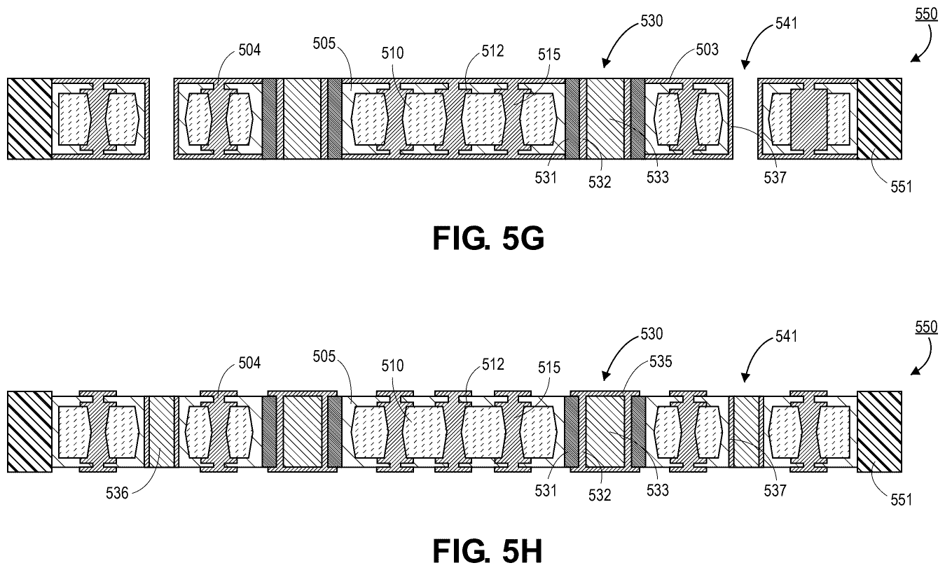

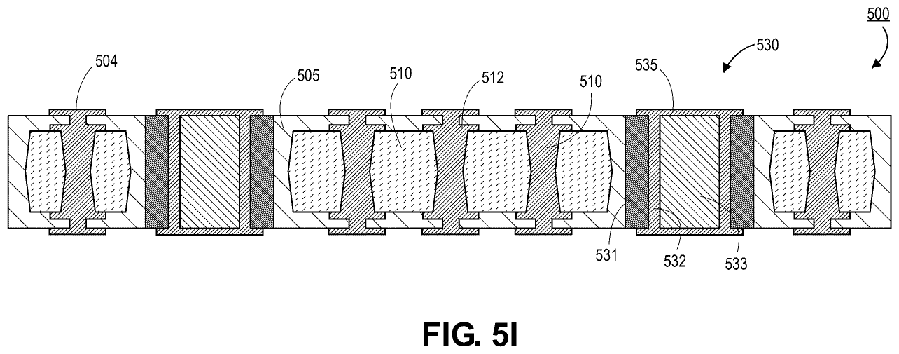

Referring now to FIGS. 5A-5I, a series of cross-sectional illustrations depicting a process for forming a package substrate 500 from a panel level process is shown, in accordance with an embodiment.

Referring now to FIG. 5A, a cross-sectional illustration of a portion of a hybrid panel 550 at a stage of manufacture is shown, in accordance with an embodiment. In an embodiment, the hybrid panel 550 may comprise a glass substrate 510. The glass substrate 510 may be similar to any of the glass cores and/or glass layers described in greater detail herein. In an embodiment, vias 515 may be provided through a thickness of the glass substrate 510. The vias 515 may be formed with any suitable process. For example, a laser assisted etching process may be used to form openings for the vias 515. In the illustrated embodiment, the vias 515 have an hourglass shaped cross-section. Though, in other embodiments the vias 515 may have a single taper or substantially vertical sidewalls. Pads 512 may be provided over and under the vias 515.

In an embodiment, the glass substrate 510 may also comprise one or more first cavities 521 and one or more second cavities 522 through a thickness of the glass substrate 510. The first cavities 521 and the second cavities 522 may have sidewalls with a double taper or any other suitable profile.

Referring now to FIG. 5B, a cross-sectional illustration of the hybrid panel 550 after the glass substrate 510 is placed within a frame 551 is shown, in accordance with an embodiment. In an embodiment, the frame 551 may comprise an organic dielectric material. As such, the hybrid panel 550 can provide protection to the edge of the glass substrate 510 while also allowing for existing processing equipment used for organic cores to process the hybrid panel 550. In an embodiment, a gap may be provided between an outer edge of the glass substrate 510 and an inner edge of the frame 551.

Referring now to FIG. 5C, a cross-sectional illustration of the hybrid panel 550 after a dielectric layer 505 is applied over the glass substrate 510 is shown, in accordance with an embodiment. The dielectric layer 505 may comprise an organic dielectric material, such as a buildup film or the like. The dielectric layer 505 may fill the first cavities 521 and the second cavities 522. In an embodiment, the dielectric layer 505 may also mechanically secure the glass substrate 510 to the frame 551.

Referring now to FIG. 5D, a cross-sectional illustration of the hybrid panel 550 after tooling holes 541 are formed through the dielectric layer 505 within the first cavities 521 is shown, in accordance with an embodiment. In an embodiment, the tooling holes 541 may be formed with a mechanical drilling process or the like.

Referring now to FIG. 5E, a cross-sectional illustration of the hybrid panel 550 after a metal layer 503 is plated over the dielectric layer 505 is shown, in accordance with an embodiment. In an embodiment, a metallic liner 537 may also be plated along sidewalls of the tooling hole 541. The plating process may include an electroplating process. In some embodiments, via openings are formed over the pads 512 prior to plating. As such, vias 504 may also be formed during the plating process.

Referring now to FIG. 5F, a cross-sectional illustration of the hybrid panel 550 after holes 542 are formed through the second cavities 522 is shown, in accordance with an embodiment. In an embodiment, the holes 542 may be formed with a mechanical drilling process. For example, alignment pins (not shown) may be provided through the tooling holes 541 in order to properly align the hybrid panel 550 to enable accurate placement of the holes 542. As described in greater detail herein, a plurality of hybrid panels 550 may be arranged in a vertical stack, and alignment pins may pass through the tooling holes in the plurality of hybrid panels. The holes 542 may then be formed through the plurality of hybrid panels 550 with a single drilling process.

Referring now to FIG. 5G, a cross-sectional illustration of the hybrid panel 550 after a device 530 is provided in each of the holes 542 is shown, in accordance with an embodiment. The device 530 may include a passive device, such as an inductor, a capacitor, or the like. In the particular embodiment shown in FIG. 5G, the device 530 is an integrated inductor that comprises a magnetic shell 531, a metal liner 532 within the magnetic shell 531, and a plug 533 within the metal liner 532. In an embodiment, the device 530 may be an integrated device 530 that is formed with processes similar to those described in greater detail herein.

Referring now to FIG. 5H, a cross-sectional illustration of the hybrid panel 550 after plugs 536 are used to fill the tooling holes 541 is shown, in accordance with an embodiment. In an embodiment, the plugs 536 may be an electrically insulating material, such as an organic dielectric material. The plug 536 may be lined by the metal liner 537 in some embodiments. FIG. 5H also illustrates a patterning process used to define pads 535 over the devices 530 and pads 512 over the vias 504 from the metal layer 503.

Referring now to FIG. 5I, a cross-sectional illustration of a package substrate 500 that is singulated from the hybrid panel 550 is shown, in accordance with an embodiment. As shown, the package substrate 500 may be singulated so that the plugs 536 of the tooling holes 541 are removed from the package substrate 500. Though, in other embodiments, the tooling holes 541 may remain within the package substrate 500, as described in greater detail herein. In an embodiment, one or more additional buildup layers may be provided over the dielectric layer 505 in order to provide any additional electrical routing needed for the package substrate 500.

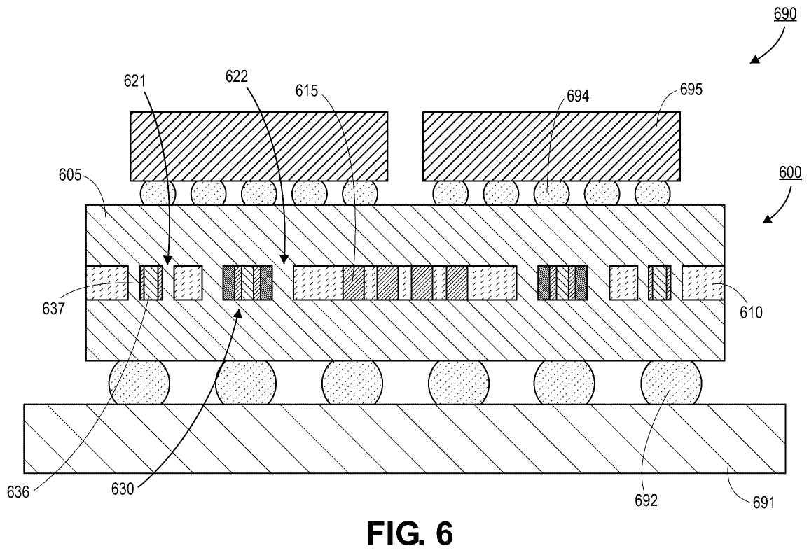

Referring now to FIG. 6, a cross-sectional illustration of an electronic system 690 is shown, in accordance with an embodiment. In an embodiment, the electronic system 690 may comprise a board 691. The board 691 may be a printed circuit board (PCB), a motherboard, and/or the like. In an embodiment, the board 691 is coupled to a package substrate 600 by interconnects 692. The interconnects 692 may include any suitable second level interconnect (SLI) architecture. For example, the interconnects 692 may comprise solder balls, sockets, pins, and/or the like.

In an embodiment, the package substrate 600 may be similar to any of the package substrates described in greater detail herein. For example, the package substrate 600 may comprise a glass core 610. In an embodiment, the glass core 610 may comprise vias 615 through a thickness of the glass core 610. The glass core 610 may also comprise a first cavity 621 and a second cavity 622. In an embodiment, a plug 636 that is lined by a metallic annulus 637 is provided within the first cavity 621. In an embodiment, the plug 636 and the metallic annulus 637 may be spaced away from a sidewall of the first cavity 621 by a portion of a dielectric layer 605 that surrounds the glass core 610. In an embodiment, a device 630 may be provided within the second cavity 622. The device 630 may comprise a passive device, such as an inductor, a capacitor, or the like. In a particular embodiment, the device 630 is a coaxial magnetic composite core inductor that is fabricated on the glass core 610.

In an embodiment, the electronic system 690 may further comprise one or more dies 695 that are coupled to the package substrate 600 by interconnects 694. The interconnects 694 may comprise any suitable first level interconnect (FLI) architecture, such as solder balls, copper bumps, hybrid bonding, and/or the like. In an embodiment, the dies 695 may comprise any suitable type of die, such as a processor (e.g., a central processing unit (CPU), a graphics processing unit (GPU), etc.), a memory, a communications die, and/or the like.

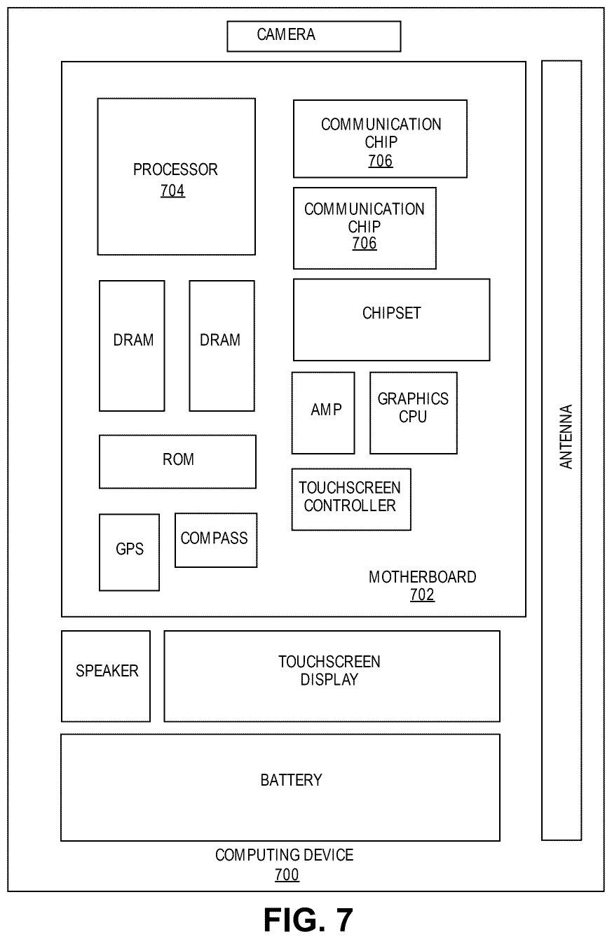

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of an electronic package that comprises a glass core with a plug in a first cavity and a device in a second cavity, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of an electronic package that comprises a glass core with a plug in a first cavity and a device in a second cavity, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate, wherein the substrate comprises a glass layer; a first cavity through a thickness of the substrate from a first surface of the substrate to a second surface of the substrate; a second cavity through the thickness of the substrate; a layer over the substrate, wherein the layer at least partially fills the first cavity and the second cavity; a plug within the first cavity, wherein a first portion of the layer separates the plug from the substrate; and a component in the second cavity, wherein a second portion of the layer separates the component from the substrate.

Example 2: the apparatus of Example 1, wherein a sidewall of the first cavity is tapered, and wherein a sidewall of the plug is oriented substantially orthogonally to the first surface of the substrate.

Example 3: the apparatus of Example 1 or Example 2, further comprising: a liner around the plug, wherein the liner comprises a metallic material.

Example 4: the apparatus of Examples 1-3, wherein the plug extends past the first surface of the substrate and the second surface of the substrate.

Example 5: the apparatus of Examples 1-4, wherein the component is an inductor.

Example 6: the apparatus of Example 5, wherein the inductor comprises: a magnetic shell; an electrically conductive liner around the magnetic shell; and an electrically insulating plug surrounded by the electrically conductive liner.

Example 7: the apparatus of Examples 1-6, further comprising: a via through the thickness of the substrate.

Example 8: the apparatus of Examples 1-7, wherein a sidewall of the second cavity is tapered, and wherein a sidewall of the component is oriented substantially orthogonally to the first surface of the substrate.

Example 9: the apparatus of Examples 1-8, wherein the layer comprises an organic dielectric material.

Example 10: the apparatus of Examples 1-9, further comprising: a board coupled to a first side of the layer; and a die coupled to a second side of the layer.

Example 11: an apparatus, comprising: a substrate, wherein the substrate comprises a glass layer, and wherein the substrate comprises a first cavity and a second cavity through a thickness of the substrate; a frame around a perimeter of the substrate, wherein the frame comprises an organic dielectric material; a layer around the substrate, wherein the layer mechanically couples the frame to the substrate, and wherein the layer at least partially fills the first cavity and the second cavity; and a plug in the first cavity, wherein the plug is separated from the substrate by a portion of the layer.

Example 12: the apparatus of Example 11, wherein the first cavity has a first diameter and the second cavity has a second diameter, and wherein the second diameter is larger than the first diameter.

Example 13: the apparatus of Example 11 or Example 12, wherein the plug is surrounded by an electrically conductive liner.

Example 14: the apparatus of Example 13, wherein the electrically conductive liner contacts only the plug and the layer.

Example 15: the apparatus of Examples 11-14, wherein a component is embedded in the second cavity.

Example 16: the apparatus of Example 15, wherein the component is an inductor.

Example 17: a package substrate, comprising: a core, wherein the core comprises a glass layer; buildup layers over and under the core; a first cavity through the core, wherein a first plug partially fills the first cavity; and a second cavity through the core, where an inductor partially fills the second cavity, and wherein the inductor comprises: a magnetic shell; an electrically conductive liner over an interior surface of the magnetic shell; and a second plug surrounded by the electrically conductive liner.

Example 18: the package substrate of Example 17, wherein the first plug is surrounded by an electrically floating metallic annulus.

Example 19: the package substrate of Example 17 or Example 18, wherein the first plug extends into the buildup layers above and below the core.

Example 20: the package substrate of Examples 17-19, further comprising: a board coupled to the package substrate; and a die coupled to the package substrate.

What is claimed is:

1. An apparatus, comprising:
a substrate, wherein the substrate comprises a glass layer;
a first cavity through a thickness of the substrate from a first surface of the substrate to a second surface of the substrate;
a second cavity through the thickness of the substrate;
a layer over the substrate, wherein the layer at least partially fills the first cavity and the second cavity;
a plug within the first cavity, wherein a first portion of the layer separates the plug from the substrate; and
a component in the second cavity, wherein a second portion of the layer separates the component from the substrate.

2. The apparatus of claim 1, wherein a sidewall of the first cavity is tapered, and wherein a sidewall of the plug is oriented substantially orthogonally to the first surface of the substrate.

3. The apparatus of claim 1, further comprising:
a liner around the plug, wherein the liner comprises a metallic material.

4. The apparatus of claim 1, wherein the plug extends past the first surface of the substrate and the second surface of the substrate.

5. The apparatus of claim 1, wherein the component is an inductor.

6. The apparatus of claim 5, wherein the inductor comprises:
a magnetic shell;
an electrically conductive liner around the magnetic shell; and
an electrically insulating plug surrounded by the electrically conductive liner.

7. The apparatus of claim 1, further comprising:
a via through the thickness of the substrate.

8. The apparatus of claim 1, wherein a sidewall of the second cavity is tapered, and wherein a sidewall of the component is oriented substantially orthogonally to the first surface of the substrate.

9. The apparatus of claim 1, wherein the layer comprises an organic dielectric material.

10. The apparatus of claim 1, further comprising:
a board coupled to a first side of the layer; and
a die coupled to a second side of the layer.

11. An apparatus, comprising:
a substrate, wherein the substrate comprises a glass layer, and wherein the substrate comprises a first cavity and a second cavity through a thickness of the substrate;
a frame around a perimeter of the substrate, wherein the frame comprises an organic dielectric material;
a layer around the substrate, wherein the layer mechanically couples the frame to the substrate, and wherein the layer at least partially fills the first cavity and the second cavity; and
a plug in the first cavity, wherein the plug is separated from the substrate by a portion of the layer.

12. The apparatus of claim 11, wherein the first cavity has a first diameter and the second cavity has a second diameter, and wherein the second diameter is larger than the first diameter.

13. The apparatus of claim 11, wherein the plug is surrounded by an electrically conductive liner.

14. The apparatus of claim 13, wherein the electrically conductive liner contacts only the plug and the layer.

15. The apparatus of claim 11, wherein a component is embedded in the second cavity.

16. The apparatus of claim 15, wherein the component is an inductor.

17. A package substrate, comprising:
a core, wherein the core comprises a glass layer;
buildup layers over and under the core;
a first cavity through the core, wherein a first plug partially fills the first cavity; and
a second cavity through the core, where an inductor partially fills the second cavity, and wherein the inductor comprises:
a magnetic shell;
an electrically conductive liner over an interior surface of the magnetic shell; and
a second plug surrounded by the electrically conductive liner.

18. The package substrate of claim 17, wherein the first plug is surrounded by an electrically floating metallic annulus.

19. The package substrate of claim 17, wherein the first plug extends into the buildup layers above and below the core.

20. The package substrate of claim 17, further comprising:
a board coupled to the package substrate; and
a die coupled to the package substrate.
